(19) United States
(12) Patent Application Publication
(10) Pub. No.: US 2025/0232810 A1
(43) Pub. Date: Jul. 17, 2025

(54) MEMORY DEVICES WITH DUAL-SIDE DISCHARGE AND METHODS FOR OPERATING THE SAME

(71) Applicant: Taiwan Semiconductor Manufacturing Company, Ltd., Hsinchu (TW)

(72) Inventors: Wei Kei Chang, Hsinchu City (TW); Shang-Hsuan Liu, Hsinchu City (TW); Yi-Cheng Huang, Hsinchu City (TW); Chou-Ying Yang, Hsinchu City (TW)

(73) Assignee: Taiwan Semiconductor Manufacturing Company, Ltd., Hsinchu (TW)

(21) Appl. No.: 18/760,660

(22) Filed: Jul. 1, 2024

Related U.S. Application Data
(60) Provisional application No. 63/621,240, filed on Jan. 16, 2024.

(51) Int. Cl. G11C 13/00

(52) U.S. Cl. CPC G11C 13/0069

(57) ABSTRACT

A memory circuit comprises a memory array, a first access circuit, and a second access circuit. The memory array may comprise a plurality of non-volatile memory cells. The non-volatile memory cells can be arranged along a plurality of first access lines and a plurality of second access lines. The first access lines and second access lines may each extend along a lateral direction across the memory array. The first access circuit can be physically disposed on a first side of the memory array in the lateral direction. The second access circuit can be physically disposed on a second side of the memory array in the lateral direction. The second side is opposite to the first side.

### CROSS-REFERENCE TO RELATED APPLICATION

This application claims priority to and the benefit of U.S. Provisional Application No. 63/621,240, filed Jan. 16, 2024, entitled “DUAL-SIDE DISCHARGE FOR RRAM WRITE OPERATION,” which is incorporated herein by reference in its entirety for all purposes.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a block diagram illustrating an example of a memory array in accordance with some embodiments.

FIG. 2. Illustrates an example schematic diagram for a resistive random access memory (RRAM) write operation in accordance with some embodiments.

FIG. 3 illustrates an example schematic diagram for dual-side discharge of a resistive random access memory (RRAM) write operation in accordance with some embodiments.

FIG. 4 illustrates example waveforms of multiple control signals to operate the memory circuit of FIG. 3 which includes plural access circuits physically disposed on the opposite sides of a memory array, in accordance with some embodiments.

FIG. 5 illustrates an example schematic diagram for dual-side discharge of a resistive random access memory (RRAM) write operation in accordance with some embodiments.

FIG. 6 illustrates an example schematic diagram for dual-side discharge of a resistive random access memory (RRAM) write operation in accordance with some embodiments.

FIG. 7 illustrates an example schematic diagram for dual-side discharge of a resistive random access memory (RRAM) write operation in accordance with some embodiments.

FIG. 8 is an example method of making a memory circuit for dual-side discharge of a resistive random access memory (RRAM) in accordance with some embodiments.

FIG. 9 illustrates a flow chart of an example method 900 for operating a memory device including access circuits physically disposed on the opposite sides of a memory array, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A resistive random access memory (RRAM) device may have a resistive material layer sandwiched between two electrodes (e.g., top electrode or bottom electrode). The resistance of the RRAM device can be set or reset to low or high to represent logic “1” or logic “0”, respectively.

In some embodiments, a “forming” process (or operation) is applied to the RRAM device. The forming process is designed to change the structure of the resistive material layer of the RRAM device such that a conductive path is generated therein. In the forming process, a forming voltage is applied to the two electrodes of the RRAM device. For example, the bottom electrode is connected to a low voltage V_{low} and the top electrode is connected to a high voltage V_{high}. The difference of V_{high}−V_{low} provides the forming voltage. In the “forming” operation, the “forming” voltage is high enough to generate conductive features in the resistive material layer. In one example, the conductive features include a plurality of conductive filament to provide a conductive path such that the resistive material layer is “on” or in low resistance state. The conductive path may be related to the lineup of the oxygen vacancies in the resistive material layer.

In another embodiment, the forming process includes two steps: a first forming step applies a first (forming) voltage Vf1 to the RRAM device and a second forming step applies a second (forming) voltage Vf2 to the RRAM device, wherein the second voltage is different from the first voltage. Particularly, in the first forming step, the first voltage is applied to the RRAM device in a first direction (or first polarity). In the second forming step, the second voltage is applied to the RRAM device in a second direction (or second polarity) that is opposite to the first direction. Therefore, the forming process is also referred to as bidirectional forming process. The first forming step is also referred to a forward forming step and the second forming step is referred to as a reverse forming step. In one embodiment, the first voltage Vf1 is greater than the second voltage Vf2 in magnitude.

In some embodiments, the RRAM device may experience a number of set and reset operation cycles (also referred to as set/reset operation cycles), such as “M” cycles. The initial resistance window is degraded over the cycling.

A recreating operation (or process) can be applied to the RRAM device to recreate filament and recover the RRAM device from the resistance degradation, in which the resistance of the RRAM device is completely or at least partially recovered to its initial stages after the “forming” process (in other words, the resistance is improved). The recreating process is designed to recover the resistance of the RRAM device. Thus, the resistances (especially the low resistance) remain a large and stable resistance window for reliable readings.

In one embodiment, the recreating process includes applying a recreating voltage to the RRAM device. The recreating voltage is applied in a polarity of a set operation. The recreating voltage is greater than a set voltage of the set operation. In one example, the recreating voltage is less than a “forming” voltage of a “forming” operation.

In another embodiment, the recreating process is a bidirectional recreating process that includes two steps: applying a first voltage in a first polarity and applying a second voltage in a second polarity to the RRAM device. In some embodiments, the set and reset operations can be based on bipolar switching effect and are applied in opposite polarities. In the present example, the set operation includes applying a set voltage to the RRAM device in the first polarity and the reset operation includes applying a reset voltage to the RRAM device in the second polarity. In such case, the first voltage in the first step of the recreating process is greater than the set voltage and the second voltage in the second step of the recreating process is greater than the reset voltage. Thereafter, the RRAM device goes through normal operations (set and reset), such as the next normal operation (M+1)^{th} cycle.

This flow continues with a recreating process is inserted in the normal operations when the resistance of the RRAM device needs to be recovered from the resistance degradation. For example, after another number of set/reset operation cycles, such as Nth cycle, another recreating process can be applied to the RRAM device to recreate filament and recover the resistance of the RRAM device. Thereafter, the RRAM device goes through normal operations (set and reset), such as the next normal operation (N+1)^{th} cycle.

The recreating process is inserted in the normal operations of the RRAM device in various modes. In one embodiment, the recreating process is inserted in the normal operations of the RRAM device in a time mode. A number N0 is predetermined according to the data of resistance degradation of the RRAM device. After every N0 set/reset operation cycles, a recreating process is applied to the RRAM device to recreate filament.

In another embodiment, the recreating process is inserted in the normal operations of the RRAM device in a detection mode. A reference current is determined for the RRAM device (also referred to as the predefined reading current), according to the reading consistence, stability and/or repeatability. During the normal operations, when the RRAM device is addressed for a normal operation, the reading current of the RRAM device is captured and compared with the reference current. If the reading current is less than the reference current, a recreating process is applied to the RRAM device to recreate filament.

In yet another embodiment, the recreating process is inserted in the normal operations of the RRAM device in a time and detection mode. During the normal operations, if the reading current is less than the reference current or when the number of set/reset operation cycles is equals to or greater than the predetermined number N0, a recreating process is applied to the RRAM device to recreate filament.

In some embodiments, a voltage or current across a resistive random access memory (RRAM) element (RE) may experience a significant reduction when a bit line (BL) length increases. This phenomenon occurs due to an increased size of the BL and source line (SL) metal resistors, resulting in a larger voltage drop (IR drop) across them. The larger IR drop may lead to a decrease in voltage across the RRAM element, thereby affecting the write window of the memory cell.

Increasing the bit line (BL) length can indeed lead to worse write performance in resistive random access memory (RRAM) due to factors like increased resistance and voltage drops along the longer BL. The existing write current typically flows in a single direction, which can exacerbate the challenges associated with longer BL lengths. To address this issue and enhance the write window, the present disclosure provides a method involving optimizing the write current direction and distribution. By carefully controlling the direction and distribution of the write current, the negative effects of longer BL lengths can be mitigated. The method enhances the write window.

The present disclosure provides a memory circuit with dual-side discharge for a resistive random access memory (RRAM) write operation. Specifically, the present disclosure provides various embodiments of a memory device or circuit including a memory array, a first access circuit, and a second access circuit. The memory array may comprise a plurality of non-volatile memory cells. In one aspect of the present disclosure, the non-volatile memory cells can be arranged along a plurality of first access lines and a plurality of second access lines. The first access lines and second access lines may each extend along a lateral direction across the memory array. The first access circuit can be physically disposed on a first side of the memory array in the lateral direction. The second access circuit can be physically disposed on a second side of the memory array in the lateral direction. The second side is opposite to the first side. Accordingly, the first access circuit can be configured to couple a programming voltage to each of the non-volatile memory cells through a corresponding one of the first access lines and provide a first conduction path through a corresponding one of the second access lines, and the second access circuit is configured to provide a second conduction path through the corresponding second access lines. As such, the equivalent resistance of a conduction (e.g., programming or reading) path across any of the memory cells can be significantly reduced, which can advantageously improve the BL path IR drop.

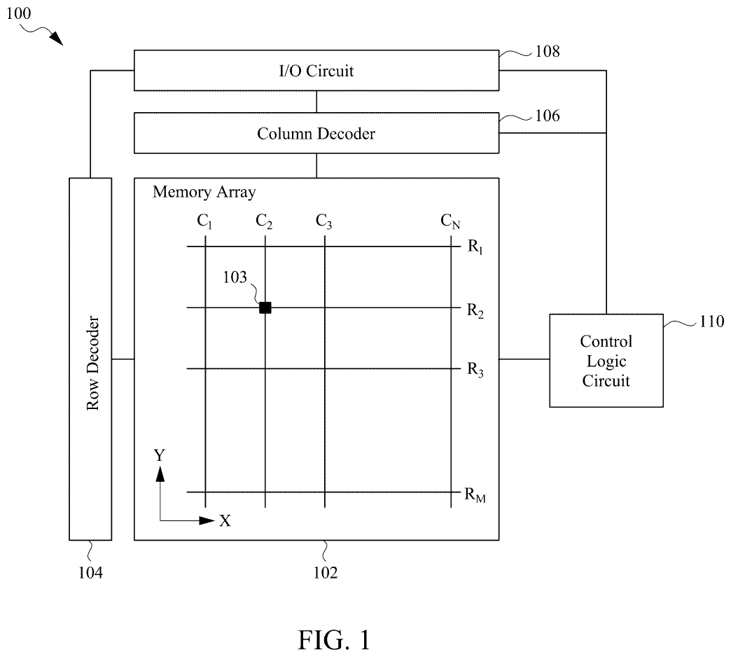

FIG. 1 illustrates a block diagram of a memory device or circuit 100, in accordance with various embodiments of the present disclosure. In the illustrated embodiment of FIG. 1, the memory device 100 includes a memory array 102, a row decoder 104, a column decoder 106, an input/output (I/O) circuit 108, and a control logic circuit 110. Despite not being shown in FIG. 1, all of the components of the memory device 100 may be coupled to each other and to the control logic circuit 110. Although, in the illustrated embodiment of FIG. 1, each component is shown as a separate block for the purpose of clear illustration, in some other embodiments, some or all of the components shown in FIG. 1 may be integrated together. For example, the memory array 102 may include an embedded I/O circuit (e.g., 108).

The memory array 102 is a hardware component that stores data. In various embodiments, the memory array 102 is embodied as a semiconductor memory device. The memory array 102 includes a plurality of memory cells (or otherwise storage units) 103. The memory array 102 includes a number of rows R₁, R₂, R₃ . . . R_{M}, each extending in a first direction (e.g., the X-direction) and a number of columns C₁, C₂, C₃ . . . C_{N}, each extending in a second direction (e.g., the Y-direction). Each of the rows and columns may include one or more conductive (e.g., metal) structures functioning as access lines. Each memory cell 103 is arranged in the intersection of a corresponding row and a corresponding column, and can be operated according to voltages or currents through the respective conductive structures of the column and row. For example, each of the rows may include one or more corresponding word lines (WLs), and each of the columns may include one or more corresponding bit lines (BLs) and one or more source lines (SLs).

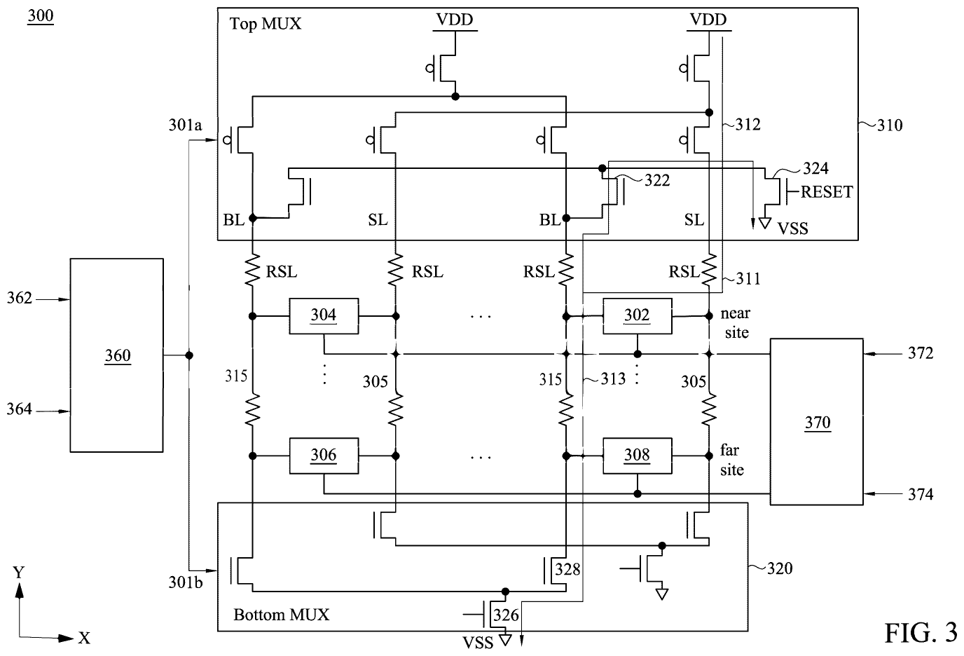

In some embodiments, each memory cell 103 is embodied as an RRAM cell, the detail of which will be discussed in FIG. 3. However, it should be understood that the memory array 102 can include any of various other non-volatile memory cells such as, for example, spin-transfer torque random-access memory (STT-RAM) cells, ferroelectric random-access memory (FeRAM) cells, magnetoresistive random-access memory (MRAM) cells, phase-change random-access memory (PCRAM) cells, etc., while remaining within the scope of the present disclosure.

The row decoder 104 is a hardware component that can receive a row address of the memory array 102 and assert a conductive structure (e.g., the WL) at that row address. The column decoder 106 is a hardware component that can receive a column address of the memory array 102 and assert a conductive structure (e.g., the BL and SL) at that column address. The I/O circuit 108 is a hardware component that can access (e.g., read, program) each of the memory cells 103 asserted through the row decoder 104 and column decoder 106. The control logic circuit 110 is a hardware component that can control the coupled components (e.g., 102 through 108).

It should be appreciated that the arrangements of the components shown in FIG. 1 is merely for illustrative purposes and does not limit the physical layout of these components. For example, although the I/O circuit 108 is shown as being arranged on a first side of the memory array 102, the I/O circuit 108 can include multiple sub-components or sub-circuits (e.g., one or more driver circuits, one or more pull-down circuits) physically disposed on different sides of the memory array 102, in accordance with various embodiments of the present disclosure. Further, such sub-components can be physically disposed between the column decoder 106 and the memory array 102. In some embodiments, the driver circuits and the pull-down circuits may sometimes be referred to as access circuits.

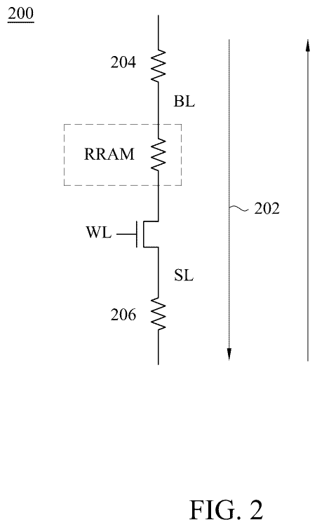

FIG. 2. Illustrates an example schematic diagram for a resistive random access memory (RRAM) write operation in accordance with some embodiments. In some embodiments, a voltage or current across a resistive random access memory (RRAM) element (RE) may experience a significant reduction when a bit line (BL) length increases. This phenomenon occurs due to the increased size of the BL and source line (SL) metal resistors, resulting in a larger voltage drop (IR drop) across them. In FIG. 2, Iwrite 202 may represent a writing current. RBL 204 and RSL 206 may represent the resistance of a bit line (BL) and a source line (SL), respectively. The larger IR drop (e.g., Iwrite*(RBL+RSL)) may lead to a decrease in voltage across the RRAM element, thereby affecting the write window of the memory cell.

In the existing technologies, a driver circuit and a pull-down circuit are typically formed on a same side of the memory array. As a size of the memory array becomes large (e.g., with an increased number of word lines/an increased length of bit lines), the RRAM cells that are formed farther from the driver circuit and the pull-down circuit commonly suffer insufficient programming voltage, mainly due to an increased voltage (IR) drop present along the extended bit lines. To this end, some technologies have proposed to place the driver circuit and the pull-down circuit on the opposite sides of a memory array. Stated another way, regardless of the current flow direction, a programming voltage is applied on one side of the memory array (through a driver circuit) and a generated current flows to ground on the other side of the memory array (through a pull-down circuit). However, the electrodes of each of the RRAM cells are typically coupled to or formed as metal lines. With the increasingly shrunken dimensions of the technology nodes, dimensions of these metal lines shrink accordingly. As such, the metal lines (or a corresponding write path) may present a higher resistance, which leads to the voltage drop issues remaining unsolved. Therefore, the existing RRAM devices have not been entirely satisfactory in certain aspects.

FIG. 3 illustrates an example schematic diagram 300 of a portion of the memory device 100 shown in FIG. 1 (hereinafter “memory circuit 300”), in accordance with some embodiments of the present disclosure. Specifically, FIG. 3 illustrate an example schematic diagram 300 for dual-side discharge of a resistive random access memory (RRAM) write operation in accordance with some embodiments. As a brief overview, the memory circuit 300 may include a memory array comprising non-volatile memory cells 302, 304, 306, 308, a first access circuit 310, and a second access circuit 320. The first access circuit 310 can be physically disposed on a first side 301a of the memory array in the lateral direction (e.g., Y-direction). The second access circuit 320 can be physically disposed on a second side 301b of the memory array in the lateral direction (e.g., Y-direction). The second side is opposite to the first side. One memory cell (e.g., 103), implemented as the RRAM cell 200 (FIG. 2), is shown in the memory array 102. In some embodiments, the memory circuit 300 may include a control circuit, which may comprise a bit line/source line (BL/SL) decoder and driver 360, and a word line (WL) decoder and driver 370. The memory circuit 300 of FIG. 3 is simplified for illustrative purposes, and thus, it should be understood that some components of FIG. 1 may be omitted in FIG. 3.

In some embodiments, the memory array may comprise a plurality of non-volatile memory cells 302, 304, 306, 308. The non-volatile memory cells 302, 304, 306, 308 can be arranged along a plurality of first access lines 305 (e.g., source lines (SL)) and a plurality of second access lines 315 (e.g., bit lines (BL)). The first access lines 305 (e.g., SL) and second access lines 315 (e.g., BL) each extends along a lateral direction (e.g., Y-direction) across the memory array. In some embodiments, each of the non-volatile memory cells 302, 304, 306, 308 may comprise an access transistor and a resistor coupled to each other in series, in which the resistor is configured to store at least a data bit. In some embodiments, each of the non-volatile memory cells 302, 304, 306, 308 may comprise an access transistor and a capacitor coupled to each other in series, in which the capacitor is configured to store at least a data bit. The non-volatile memory cells can retain stored data in the absence of power, whereas the volatile memory device loses its data memory contents when power is lost. The non-volatile memory cells can include any of various non-volatile memory cells such as, for example, resistive random access memory (RRAM) cells, spin-transfer torque random-access memory (STT-RAM) cells, ferroelectric random-access memory (FeRAM) cells, magnetoresistive random-access memory (MRAM) cells, phase-change random-access memory (PCRAM) cells, etc., while remaining within the scope of the present disclosure. In some embodiments, the non-volatile memory cell can be configured to be programmed from a first resistance state (e.g., low resistance state) to a second resistance state (e.g., high resistance state).

In some embodiments, the first access circuit 310 (e.g., top MUX) may be physically disposed on a first side 301a of the memory array in the lateral direction (e.g., Y-direction). In some embodiments, the first access circuit 310 can be a multiplexer (MUX) to select one input from multiple inputs and route it to a single output based on control signals provided. The first access circuit 310 can be configured to couple a programming voltage to each of the non-volatile memory cells 302, 304, 306, 308 through a corresponding one of the first access lines 305 (e.g., source line (SL)) and provide a first conduction path 312 (e.g., Iwrite 2) through a corresponding one of the second access 315 (e.g., bit lines (BL)). In some embodiments, the first conduction path 312 may extend from the corresponding non-volatile memory cell 302, through a first transistor 322 and a second transistor 324, to ground (VSS). In some embodiments, the first conduction path 312 may include the first 322 and second transistors 324. In some embodiments, one source/drain terminal of the first transistor 322 can be connected to the second access line 315 (e.g., BL). One source/drain terminal of the second transistor 324 can be connected to the ground (e.g., VSS). In some embodiments, the first access circuit 310 may comprise a first sub-circuit and a second sub-circuit.

In some embodiments, the second access circuit 320 (e.g., bottom MUX) may be physically disposed on a second side 301b of the memory array in the lateral direction (e.g., Y-direction). The second side 301b is opposite to the first side 301a. In some embodiments, the second access circuit 320 can be a multiplexer (MUX) to select one input from multiple inputs and route it to a single output based on control signals provided. The second access circuit 320 can be configured to provide a second conduction path 313 (e.g., Iwrite 1) through the corresponding second access lines 315. The second conduction path 313 may extend from the corresponding non-volatile memory cell 302, through a third transistor 326, to ground (VSS). The second access circuit may include the third transistor 326. One source/drain terminal of the third transistor 326 can be connected to the second access line 315, with the other source/drain terminal of the third transistor 326 connected to the ground (VSS). In some embodiments, the second access circuit 320 may comprise a third sub-circuit and a fourth sub-circuit.

In some embodiments, the first to third transistors 322, 324, 326 can be configured to be concurrently activated, when the programming voltage is applied to corresponding non-volatile memory cell 302 through one of the first access lines 305. When each of the non-volatile memory cells is configured to be programmed by a current flowing through the corresponding first access line 305 and the non-volatile memory cell itself, the current (e.g., Iwrite) is configured to break into two separated currents (e.g., Iwrite 1 and Iwrite 2) flowing through the first conduction path 312 and the second conduction path 313, respectively. In some embodiments, the second access circuit 320 may comprise a third sub-circuit and a fourth sub-circuit. The first sub-circuit can be configured to couple a programming voltage to the memory cell through the first access line 305. The second and third sub-circuits can be each configured to provide a respective conduction path from the memory cell to ground (VSS), while the fourth sub-circuit being deactivated.

In some embodiments, the memory circuit 300 may include a control circuit. The control circuit can be a hardware component that can control the coupled components (e.g., a memory array 302, 304, 306, 308, a first access circuit 310, and/or a second access circuit 320). The control circuit may comprise a WL decoder and WL driver 370, and a BL/SL decoder and BL/SL driver 360. The WL decoder and WL driver 370 can be a hardware component that can receive a WL address 372 (and XE signal 374) of the memory circuit 300 and assert a conductive structure (e.g., the WL) at that WL address. The BL/SL decoder and BL/SL driver 360 can be a hardware component that can receive a BL/SL address 362 (and YE signal 364) of the memory circuit 300 and assert a conductive structure (e.g., the BL) at that BL/SL address. The selection of bit line (BL) and source line (SL) in a resistive random access memory (RRAM) array can be determined by the YE 364 and BL/SL address 362 signals for BL/SL and the XE 374 and WL address 372 signals for WL. When a cell is selected, the write current flows from the top multiplexer (MUX) through the selected cell, traversing from the SL to the BL, and then discharges to ground at the bottom side (VSS). However, this process is affected by the presence of metal resistors in the BL and SL, which cause an IR drop. As the number of cells in the array increases, the product of the write current and the sum of BL and SL resistances (Iwrite*(RBL+RSL)) becomes larger. This larger IR drop reduces the voltage across the RRAM cell, leading to a deterioration in the write window and potentially impacting the reliability and performance of the memory array. The present disclosure provides two separated currents flowing through the first conduction path 312 (e.g., Iwrite 2) and the second conduction path 313 (e.g., Iwrite 3) to reduce the IR drop.

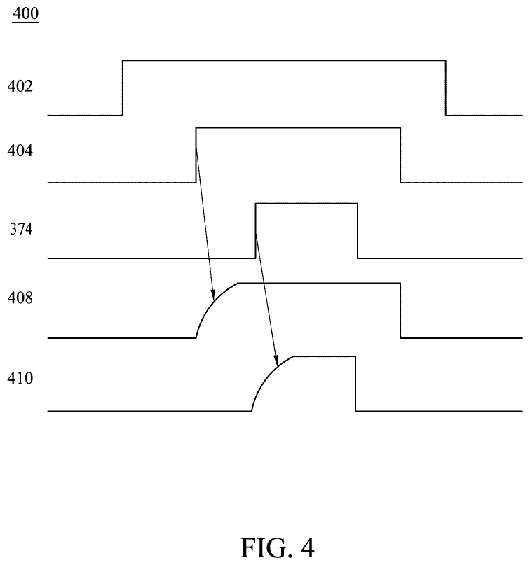

FIG. 4 illustrates example waveforms 400 of multiple control signals to operate the memory circuit of FIG. 3 which includes plural access circuits physically disposed on the opposite sides of a memory array, in accordance with some embodiments.

The timing waveform 400 for the reset operation in resistive random access memory (RRAM) may comprise three distinct steps. Firstly, the RESET signal 402 goes high to initiate the reset period and activate the pull-down path. Next, the BLE signal 404 rises, selecting the target bit line (BL) and source line (SL) 408 while activating the corresponding top and bottom multiplexers 310, 320. This allows the supply voltage to pass through either the BL or SL, setting the stage for the reset operation. Finally, the XE signal 374 is activated, selecting and enabling the word line (WL) 410. At this point, the reset operation commences, utilizing the current from the power supply to drive the pull-down device and complete the reset process effectively.

In some embodiments, in the modified waveform for the reset operation in resistive random access memory (RRAM), a pull-down device can be implemented at the top multiplexer 310. The pull-down device is activated by the same RESET signal used for the reset operation, thereby enabling a discharge path during the reset process. Despite the addition of the device and the necessary control logic, the area penalty incurred is very minor. This enhancement ensures more efficient discharge during reset, contributing to improved reliability and performance of the RRAM memory system without significantly increasing the overall complexity or footprint of the circuitry.

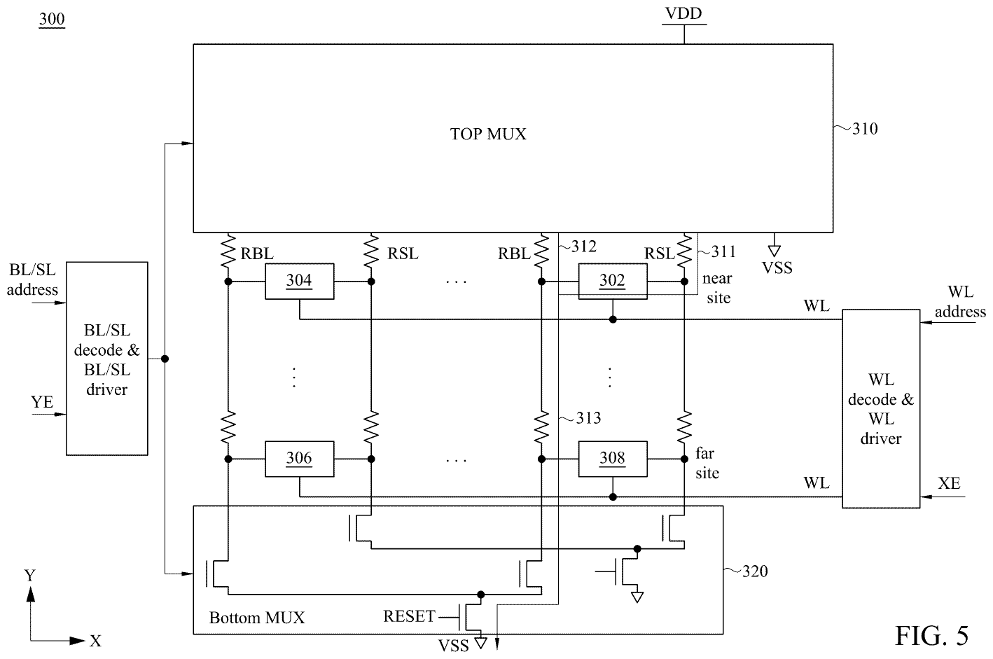

FIG. 5 illustrates an example schematic diagram for dual-side discharge of a resistive random access memory (RRAM) write operation in accordance with some embodiments. FIG. 5 features a higher-level block diagram 300 showcasing a top multiplexer (MUX) 310 that offers two distinct conductive paths 312, 313 corresponding to VDD and VSS, respectively. This configuration allows for versatile routing of electrical signals within the circuit, with VDD representing the supply voltage and VSS representing the ground connection. The top MUX 310 serves as a crucial component in managing the flow of current and voltage across the system, providing flexibility and control over the circuit's operation. By incorporating these two conductive paths 312, 313, the memory circuit 300 can effectively handle different voltage levels and ensure proper functioning of the integrated circuitry.

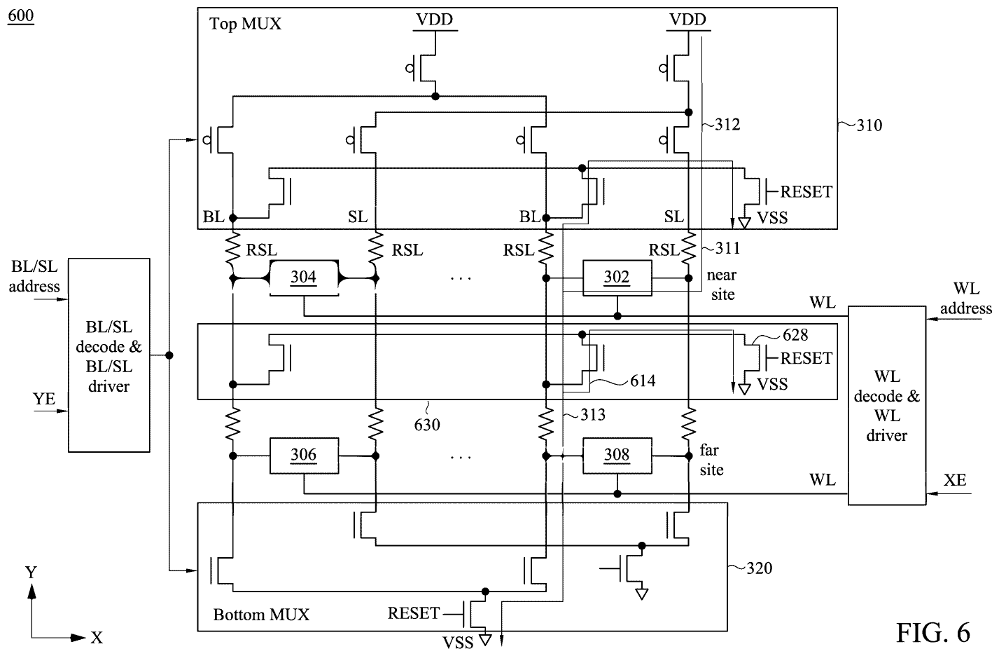

FIG. 6 illustrates an example schematic diagram 600 for dual-side discharge of a resistive random access memory (RRAM) write operation in accordance with some embodiments. FIG. 6 illustrates an alternative example of FIG. 3 by introducing a middle multiplexer (MUX) 630 (e.g., extra middle side pull down device). The memory circuit 600 may include a memory array 302, 304, 306, 308, a first access circuit 310, a second access circuit 320, and a third access circuit 630. The memory circuit 600 of FIG. 6 is substantially similar to the memory circuit 300 of FIG. 3, except for the additional third access circuit 630. The third access circuit 630 may expand the available conductive paths within the memory circuit 600.

In some embodiments, the third access circuit 630 (e.g., middle MUX) may be physically disposed on a middle of the memory array in the lateral direction (e.g., Y-direction). The third access circuit 630 can be configured to provide a third conduction path 614 (e.g., Iwrite 3) through the corresponding second access lines 315. In some embodiments, the third access circuit 630 can be a multiplexer (MUX) to select one input from multiple inputs and route it to a single output based on control signals provided. The third access circuit 630 can be configured to provide a third conduction path 614 (e.g., Iwrite 3) through the corresponding second access lines 315. The third conduction path 614 may extend from the corresponding non-volatile memory cell 302, through a fifth transistor 628, to ground (VSS). The third access circuit 630 may include the fifth transistor 628. One source/drain terminal of the fifth transistor 628 can be connected to the second access line 315, with the other source/drain terminal of the fifth transistor 628 connected to the ground (VSS).

In some embodiments, the first to fifth transistors can be configured to be concurrently activated, when the programming voltage is applied to corresponding non-volatile memory cell 302 through one of the first access lines 305. When each of the non-volatile memory cells is configured to be programmed by a current flowing through the corresponding first access line 305 and the non-volatile memory cell itself, the current (e.g., Iwrite) is configured to break into three separated currents (e.g., Iwrite 1, Iwrite 2, and Iwrite 3) flowing through the first conduction path 312, the second conduction path 313, and the third conduction path 614, respectively.

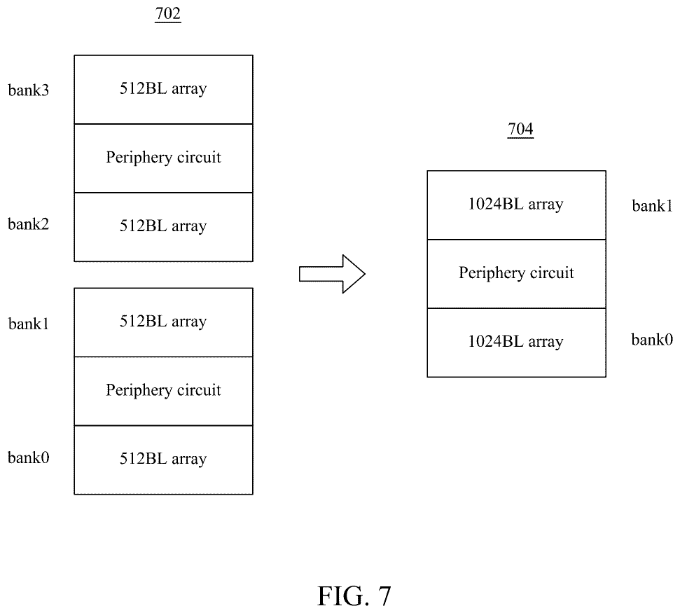

FIG. 7 illustrates an example schematic diagram for dual-side discharge of a resistive random access memory (RRAM) write operation in accordance with some embodiments. The introduction of the memory circuit 300 only a minor area penalty, making it a practical addition without significantly increasing the overall footprint. Moreover, the waveform remains unchanged from the original design, requiring no extra control circuitry. The method involves separating the total current, Iwrite, into two or three paths through BL discharge, leading to less current flowing through the BL and consequently reducing the IR drop at the BL side. As a result, with the same supply power, this invention achieves better voltage across the RRAM element due to the reduced BL side IR drop. Even in a 1024-bit line (BL) array 704, the voltage across the RRAM element surpasses that of the original 512-bit line array architecture 702. This advancement allows for larger bank sizes and a reduced number of banks, contributing to better area savings by minimizing periphery circuitry and bank requirements.

By adding an extra pull-down device at the top multiplexer (MUX) side and activating both top and bottom pull-down devices during the RESET operation, the current flow can be divided into two paths. This division of current leads to a reduction in the total bit line (BL) path IR drop, improving overall performance. The dual-side discharge method implemented through the devices further enhances the write window of the system. As a result of these enhancements, the voltage across the resistive random access memory (RRAM) can increase by about 10% with 512 word lines (WL) and by about 18% with 1024 WL. Additionally, the difference in voltage between the near and far sites of the memory is reduced, contributing to more uniform and reliable operation across the memory array.

The enhancements made to the bit line (BL) path have resulted in an improved reduction in the IR drop along the path. The improvement directly translates into an increase in the voltage across the resistive element (RE), rising from about 0.96V to about 1.05V with 512 word lines (WL). Even with a larger array of 1,024 WL, the worst-case voltage remains at about 0.99V, surpassing the performance of the original 512 WL configuration. Additionally, these improvements have led to a reduction in the voltage difference between the near and far sites of the memory, contributing to more uniform and reliable voltage distribution across the memory array.

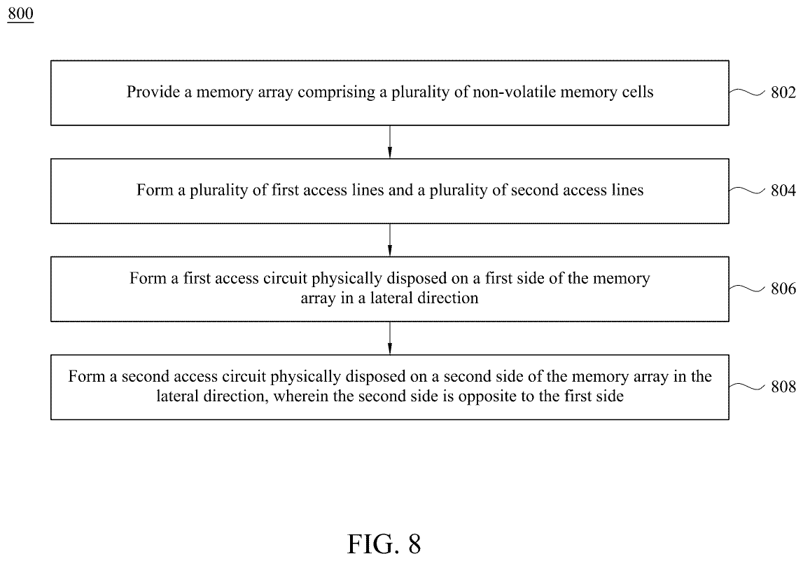

FIG. 8 is an example method of making a memory circuit for dual-side discharge of a resistive random access memory (RRAM) in accordance with some embodiments. In overview, the method 800 may include making memory arrays to avoid the negative effects of longer BL lengths.

Referring to (802), and in some embodiments, a memory array comprising a plurality of non-volatile memory cells 302, 304, 306, 308 can be provided. In some embodiments, each of the non-volatile memory cells 302, 304, 306, 308 may comprise an access transistor and a resistor coupled to each other in series, in which the resistor is configured to store at least a data bit. In some embodiments, each of the non-volatile memory cells 302, 304, 306, 308 may comprise an access transistor and a capacitor coupled to each other in series, in which the capacitor is configured to store at least a data bit. The non-volatile memory cells can retain stored data in the absence of power, whereas the volatile memory device loses its data memory contents when power is lost. The non-volatile memory cells can include any of various non-volatile memory cells such as, for example, resistive random access memory (RRAM) cells, spin-transfer torque random-access memory (STT-RAM) cells, ferroelectric random-access memory (FeRAM) cells, magnetoresistive random-access memory (MRAM) cells, phase-change random-access memory (PCRAM) cells, etc., while remaining within the scope of the present disclosure.

Referring to (804), and in some embodiments, a plurality of first access lines 305 and a plurality of second access lines 315 can be formed. The first access lines 305 and second access lines 315 may each extend along a lateral direction (e.g., Y-direction) across the memory array. The non-volatile memory cells 302, 304, 306, 308 can be arranged along a plurality of first access lines 305 (e.g., source lines (SL)) and a plurality of second access lines 315 (e.g., bit lines (BL)). The first access lines 305 (e.g., SL) and second access lines 315 (e.g., BL) each extends along a lateral direction (e.g., Y-direction) across the memory array.

Referring to (806), and in some embodiments, a first access circuit 310 physically disposed on a first side 301a of the memory array in the lateral direction (e.g., Y-direction) can be formed. In some embodiments, the first access circuit 310 can be a multiplexer (MUX) to select one input from multiple inputs and route it to a single output based on control signals provided. The first access circuit 310 can be configured to couple a programming voltage to each of the non-volatile memory cells 302, 304, 306, 308 through a corresponding one of the first access lines 305 (e.g., source line (SL)) and provide a first conduction path 312 (e.g., Iwrite 2) through a corresponding one of the second access lines 315 (e.g., bit lines (BL)).

Referring to (808), and in some embodiments, a second access circuit 320 physically disposed on a second side 301b of the memory array in the lateral direction can be formed. The second side 301b is opposite to the first side 301a. In some embodiments, the second access circuit 320 can be a multiplexer (MUX) to select one input from multiple inputs and route it to a single output based on control signals provided. The second access circuit 320 can be configured to provide a second conduction path 313 (e.g., Iwrite 1) through the corresponding second access lines 315. In some embodiments, a third access circuit 630 physically disposed on a middle of the memory array in the lateral direction (e.g., Y-direction) can be formed.

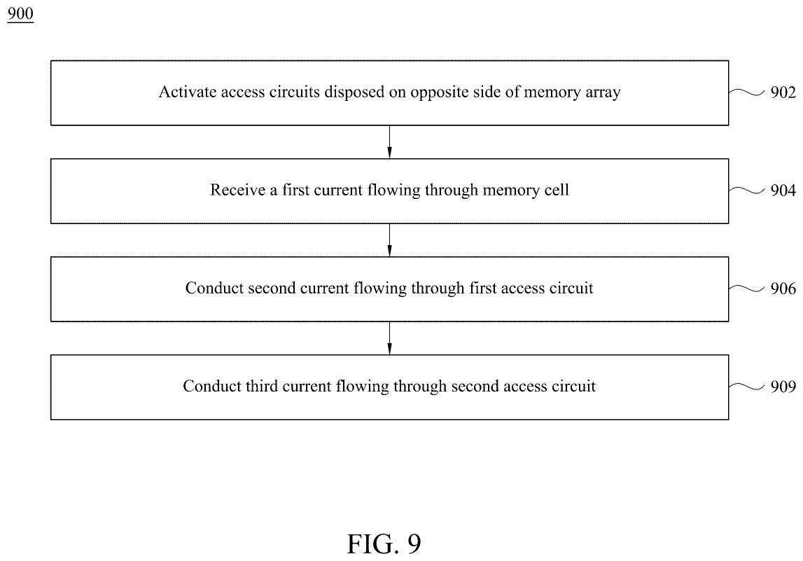

FIG. 9 illustrates a flow chart of an example method 900 for operating a memory device including access circuits physically disposed on the opposite sides of a memory array, in accordance with some embodiments. For example, at least some of the operations of the method 900 can be performed to write/read a memory cell (e.g., 103) based on at least two conduction paths. Thus, in the following discussion of the methods 900, the reference numerals used in the figures above (e.g., FIGS. 1-7) may be reused. It is noted that the method 900 is merely an example and is not intended to limit the present disclosure. Accordingly, it is understood that additional operations may be provided before, during, and after the method 900 of FIG. 9, and that some other operations may only be briefly described herein.

The method 900 starts with operations 902 in which a plurality of access circuits that are physically disposed on the opposite sides of a memory array are activated. In some embodiments, a first access circuit (e.g., 310) physically disposed on a first side of a memory array in a lateral direction can be activated. In some embodiments, a second access circuit (e.g., 320) physically disposed on a second side of the memory array in the lateral direction can be activated. The second side can be opposite to the first side. In some embodiments, the memory array (e.g., 300) includes a plural number of memory cells (e.g., RRAM cells 302, 304, 306, 308) arranged over a number of columns and a number of rows. Along each column, a subset of the memory cells are coupled to one another through a bit line and a source line, each of which may extend along the Y-direction; and along each row, another subset of the memory cells are coupled to one another through a word line, which may extend along the X-direction.

In one aspect of the present disclosure (e.g., the memory circuit 300 of FIG. 3), a first access circuit (e.g., 310) is physically disposed on a first side 301a of the memory array along the Y-direction, and a second access circuit (e.g., 320) is physically disposed on the second side 301b of the memory array along the Y-direction. To access (e.g., program, read) the memory array, the plural access circuits can be activated. Specifically, each access circuit can include two sub-circuits that may be alternately activated based on a logic state to be programmed to a corresponding memory cell. With at least two of the access circuits disposed on the opposite sides of the memory array, each memory cell of the memory array can be programmed/read through at least two conduction paths, which can advantageously decrease an equivalent resistance along the conduction paths.

The method 900 proceeds to operation 904 in which a first current flowing/voltage can be provided to the memory cell. Continuing with the same example above, each of the non-volatile memory cells can be configured to be programmed by a current flowing through the corresponding first access line and the non-volatile memory cell itself. The current can be configured to break into two separated currents flowing (e.g., second current flowing, third current flowing) through the first conduction path and the second conduction path, respectively. In some embodiments, the voltage may be a programming voltage (VBL) when the memory cell is selected to be programmed. Based on the logic state to be programmed, different sub-circuits of the access circuits can be activated to couple the programming voltage to the memory cell. When the sub-circuits 322, 324, and 326 are activated (e.g., writing a logic 0 to the memory cell), the programming voltage can be coupled to the memory cell through its corresponding bit line.

The method 900 proceeds to operation 906 in which a second current is conducted to flow through the first access circuit via a first conduction path (e.g., Iwrite 2), and operation 909 in which a third current is conducted to flow through the second access circuit via a second conduction path (e.g., Iwrite1). In some embodiments, the operations 906 and 909 may be performed at the same time. Still with the same example above (when writing a logic 0 to the memory cell), the sub-circuits 322, 324, and 326 are activated. Consequently, a first conduction path (e.g., 312), extending from a corresponding non-volatile memory cell 302, through a first transistor 322 and a second transistor 324, to ground (VSS), can be formed. A second conduction path (e.g., 313), extending from the corresponding non-volatile memory cell 302, through a third transistor 326, to ground (VSS), can be formed. By carefully controlling the direction and distribution of the write current, the negative effects of longer BL lengths (e.g., IR drop) can be mitigated. In certain embodiments, the method 900 proceeds to an operation in which a fourth current is conducted to flow through a third access circuit via a third conduction path (e.g., Iwrite 3). In some embodiments, the third access circuit can be physically disposed on a middle of the memory array in the lateral direction. The third access circuit can be configured to provide the third conduction path through the corresponding second access lines.

As used herein, the terms “about” and “approximately” generally mean plus or minus 10% of the stated value. For example, about 0.5 would include 0.45 and 0.55, about 10 would include 9 to 11, about 1000 would include 900 to 1100.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory circuit, comprising:
a memory array comprising a plurality of non-volatile memory cells, wherein the non-volatile memory cells are arranged along a plurality of first access lines and a plurality of second access lines, the first access lines and second access lines each extending along a lateral direction across the memory array;
a first access circuit physically disposed on a first side of the memory array in the lateral direction; and
a second access circuit physically disposed on a second side of the memory array in the lateral direction, wherein the second side is opposite to the first side;
wherein the first access circuit is configured to couple a programming voltage to each of the non-volatile memory cells through a corresponding one of the first access lines and provide a first conduction path through a corresponding one of the second access lines, and the second access circuit is configured to provide a second conduction path through the corresponding second access lines.

2. The memory circuit of claim 1, wherein each of the non-volatile memory cells comprises an access transistor and a resistor coupled to each other in series, in which the resistor is configured to store at least a data bit.

3. The memory circuit of claim 1, wherein each of the non-volatile memory cells comprises an access transistor and a capacitor coupled to each other in series, in which the capacitor is configured to store at least a data bit.

4. The memory circuit of claim 1, wherein the first conduction path extends from the corresponding non-volatile memory cell, through a first transistor and a second transistor, to ground, and the second conduction path extends from the corresponding non-volatile memory cell, through a third transistor, to ground.

5. The memory circuit of claim 4, wherein the first access circuit includes the first and second transistors, and the second access circuit includes the third transistor.

6. The memory circuit of claim 4, wherein the first to third transistors are configured to be concurrently activated, when the programming voltage is applied to corresponding non-volatile memory cell through one of the first access lines.

7. The memory circuit of claim 4, wherein one source/drain terminal of the first transistor is connected to the second access line, with one source/drain terminal of the second transistor connected to the ground.

8. The memory circuit of claim 4, wherein one source/drain terminal of the third transistor is connected to the second access line, with the other source/drain terminal of the third transistor connected to the ground.

9. The memory circuit of claim 1, wherein when each of the non-volatile memory cells is configured to be programmed by a current flowing through the corresponding first access line and the non-volatile memory cell itself, the current is configured to break into two separated currents flowing through the first conduction path and the second conduction path, respectively.

10. The memory circuit of claim 9, wherein the non-volatile memory cell is configured to be programmed from a first resistance state to a second resistance state.

11. The memory circuit of claim 1, comprising:
a third access circuit physically disposed on a middle of the memory array in the lateral direction, wherein the third access circuit is configured to provide a third conduction path through the corresponding second access lines.

12. A memory circuit, comprising:
a memory cell coupled between a first access line and a second access line, wherein the first access line and the second access line both extend along a lateral direction;
a first access circuit physically disposed on a first side of the memory cell in the lateral direction, wherein the first access circuit comprises a first sub-circuit and a second sub-circuit; and
a second access circuit physically disposed on a second side of the memory cell in the lateral direction, the second side being opposite to the first side, wherein the second access circuit comprises a third sub-circuit and a fourth sub-circuit;
wherein the first sub-circuit is configured to couple a programming voltage to the memory cell through the first access line, the second and third sub-circuits are each configured to provide a respective conduction path from the memory cell to ground, while the fourth sub-circuit being deactivated.

13. The memory circuit of claim 12, wherein the memory cell comprises an access transistor and a resistor coupled to each other in series, in which the resistor is configured to store at least a data bit.

14. The memory circuit of claim 12, wherein the memory cell comprises an access transistor and a capacitor coupled to each other in series, in which the capacitor is configured to store at least a data bit.

15. The memory circuit of claim 12, wherein the first sub-circuit is configured to provide a first conduction path through the second access line, and the third sub-circuit is configured to provide a second conduction path through the second access line.

16. The memory circuit of claim 15, wherein the first conduction path extends from the memory cell, through a first transistor and a second transistor, to ground, and the second conduction path extends from the memory cell, through a third transistor, to ground.

17. The memory circuit of claim 16, wherein the first access circuit includes the first and second transistors, and the second access circuit includes the third transistor.

18. The memory circuit of claim 16, wherein the first to third transistors are configured to be concurrently activated, when the programming voltage is applied to corresponding memory cell through the first access line.

19. A method for operating a memory circuit, comprising:
activating a first access circuit physically disposed on a first side of a memory array in a lateral direction, wherein the memory array comprises a plurality of non-volatile memory cells, wherein the non-volatile memory cells are arranged along a plurality of first access lines and a plurality of second access lines, the first access lines and second access lines each extending along the lateral direction across the memory array;
activating a second access circuit physically disposed on a second side of the memory array in the lateral direction, wherein the second side is opposite to the first side;
receiving a first current flowing through the memory array;
conducting a second current flowing through the first access circuit via a first conduction path; and
conducting a third current flowing through the second access circuit via a second conduction path,
wherein the first access circuit is configured to couple a programming voltage to each of the non-volatile memory cells through a corresponding one of the first access lines and provide the first conduction path through a corresponding one of the second access lines, and the second access circuit is configured to provide the second conduction path through the corresponding second access lines.

20. The method of claim 19, further comprising:
conducting a fourth current flowing through a third access circuit via a third conduction path, wherein the third access circuit is physically disposed on a middle of the memory array in the lateral direction, wherein the third access circuit is configured to provide the third conduction path through the corresponding second access lines.
